(19) United States
(12) Patent Application Publication
(10) Pub. No.: US 2025/0081406 A1
(43) Pub. Date: Mar. 6, 2025

(54) REFRIGERATION SYSTEM AND CONTROL METHOD FOR DATA CENTER, AND DATA CENTER

(71) Applicant: Hebei Qinhuai Data Co., Limited., Zhangjiakou City (CN)

(72) Inventor: Binghua ZHANG, Zhangjiakou City, Hebei Province (CN)

(21) Appl. No.: 18/817,506

(22) Filed: Aug. 28, 2024

(30) Foreign Application Priority Data
Sep. 4, 2023 (CN) 202311132338.8

(51) Int. Cl. H05K 7/20

(52) U.S. Cl. CPC H05K 7/20827; H05K 7/20327; H05K 7/20354; H05K 7/20836

(57) ABSTRACT

The present disclosure relates to the field of data center technology and discloses a refrigeration system for a data center. The data center includes a refrigeration system and at least one computer room internally provided with at least one liquid-cooled server configured to dissipate heat through a liquid-cooled pipeline. The refrigeration system includes a water-cooled precision air conditioner configured to dissipate heat from the liquid-cooled server in the computer room, and a coolant distribution apparatus configured to dissipate heat from the liquid-cooled pipeline of the liquid-cooled server in the computer room.

### CROSS REFERENCE TO RELATED APPLICATION

This application claims priority to Chinese Patent Application No. 202311132338.8, titled “REFRIGERATION SYSTEM AND CONTROL METHOD FOR DATA CENTER, AND DATA CENTER” and filed to the China National Intellectual Property Administration on Sep. 4, 2023, the entire contents of which are incorporated herein by reference.

### TECHNICAL FIELD

The present disclosure relates to the field of data center technology, and more particularly, to a refrigeration system and a control method for a data center, and the data center.

### BACKGROUND

Currently, with the improvement of performance of servers in data centers, demands for heat dissipation of server chips and other components are also increasing accordingly.

Cold plate liquid-cooled servers are used in related technologies to solve the heat dissipation problem of the servers in the data centers. However, liquid cooling systems in the cold plate liquid-cooled servers can only dissipate heat from components with higher heat generation such as the server chips. Other components with lower heat generation in the servers rely on the servers' own cooling fans to dissipate heat, which results in lower heat dissipation efficiency.

It is to be noted that the above information disclosed in this Background section is only for enhancement of understanding of the background of the present disclosure and therefore it may contain information that does not form the prior art that is already known to a person of ordinary skill in the art.

### SUMMARY

To have a basic understanding of some aspects of the disclosed embodiments, a brief summary is provided below. The summary neither is a general review, nor is intended to determine key/important constituent elements or describe a protection scope of these embodiments, but rather serves as a preface to the detailed description that follows.

The embodiments of the present disclosure provide a refrigeration system and a control method for a data center, and the data center, which can improve heat dissipation efficiency of a server in the data center.

In some embodiments, the data center includes a refrigeration system and at least one computer room internally provided with at least one liquid-cooled server configured to dissipate heat through a liquid-cooled pipeline. The refrigeration system includes:
a water-cooled precision air conditioner configured to dissipate heat from the at least one liquid-cooled server in the computer room;
a coolant distribution apparatus configured to dissipate heat from the liquid-cooled pipeline of the at least one liquid-cooled server in the computer room; and
a cold source provided with a chilled water circuit comprising a first chilled water circuit and a second chilled water circuit; where the first chilled water circuit is connected to the water-cooled precision air conditioner to provide chilled water to the water-cooled precision air conditioner; and the second chilled water circuit is connected to the coolant distribution apparatus to provide the chilled water to the coolant distribution apparatus.

In some embodiments, the refrigeration control method for the data centers is applied to the aforementioned refrigeration system, which also includes a first temperature sensor configured to detect a first ambient temperature inside the computer room. The method includes:
obtaining the first ambient temperature inside the computer room when the coolant distribution apparatus is started up; and
controlling to switch on the water-cooled precision air conditioner when the first ambient temperature is higher than a set temperature.

In some embodiments, the data center includes at least one data center, which is internally provided with at least one liquid-cooled server configured to dissipate heat through the liquid-cooled pipeline. The data center also includes the aforementioned refrigeration system.

The refrigeration system and the control method for the data center and the data center provided in the embodiments of the present disclosure can achieve following technical effects.

In the embodiments of the present disclosure, the liquid-cooled server transfers heat generated by itself to outside of the computer room through the liquid in the liquid-cooled pipeline, to dissipate the heat from the liquid-cooled pipeline by means of the coolant distribution apparatus outside the computer room. In this way, heat can be dissipated from components with higher heat generation such as a chip of the liquid-cooled server. Heat dissipated from other components with lower heat generation in the liquid-cooled server may be dissipated into interior of the computer room (such as a channel of the computer room). The heat inside the computer room can be transferred to the outside of the computer room by means of the water-cooled precision air conditioner, to dissipate the heat inside the computer room. In this way, the liquid-cooled server provided in the embodiments of the present disclosure can dissipate heat by means of the coolant distribution apparatus and the water-cooled precision air conditioner. Compared to a mode where the liquid-cooled server relies on the liquid-cooled pipeline and its own fan to dissipate heat, heat dissipation efficiency of the server in the data center can be improved.

Both the foregoing general description and the following detailed description are exemplary and explanatory only and are not intended to limit the present disclosure.

### BRIEF DESCRIPTION OF THE DRAWINGS

Exemplary descriptions are made to one or more embodiments with reference to pictures in the corresponding drawings, and these exemplary descriptions and drawings do not constitute limitations on the embodiments, and elements with the same reference numerals in the drawings are denoted as similar elements. Unless otherwise stated, the drawings do not constitute a scale limitation, in which:

FIG. 1 is a schematic diagram of a data center according to an embodiment of the present disclosure;

FIG. 2 is a schematic diagram of a water-cooled precision air conditioner according to an embodiment of the present disclosure;

FIG. 3 is a schematic diagram of a coolant distribution apparatus according to an embodiment of the present disclosure;

FIG. 4 is a schematic diagram of a cold source according to an embodiment of the present disclosure;

FIG. 5 is a schematic diagram of electrical connection of a refrigeration system for a data center according to an embodiment of the present disclosure;

FIG. 6 is a flowchart of a refrigeration control method for a data center according to an embodiment of the present disclosure; and

FIG. 7 is a schematic diagram of a refrigeration control apparatus for a data center according to an embodiment of the present disclosure.

Reference numerals in the attached drawings:
data center 100; computer room 1; refrigeration system 2; liquid-cooled server 11; liquid-cooled pipeline 12; water-cooled precision air conditioner 21; coolant distribution apparatus 22; cold source 23; first chilled water circuit 24; second chilled water circuit 25; controller 26; first temperature sensor 27; second temperature sensor 28; first water temperature sensor 29; second water temperature sensor 20; compressor 211; liquid-cooled condenser 212; electronic expansion valve 213; evaporator 214; fluorine pump 215; one-way valve 216; plate heat exchanger 221; water pump 222; first branch 223; second branch 224; cooling apparatus 231; fan 232; circulating pump 233; and auxiliary heating apparatus 234.

### DETAILED DESCRIPTION

To gain a more detailed understanding of the characteristics and technical contents of the embodiments of the present disclosure, a detailed description is made to implementation of the embodiments of the present disclosure in conjunction with the accompanying drawings, which serve for reference only and are not intended to limit the embodiments of the present disclosure. In the following technical description, for convenience of explanation, multiple details are provided to provide a comprehensive understanding of the disclosed embodiments. However, one or more embodiments can still be implemented without these details. In other cases, to simplify the drawings, familiar structures and apparatuses can be simplified for display.

In the specification, the claims and the foregoing accompanying drawings of the embodiments of the present disclosure, a term such as “first” or “second” is intended to separate between similar objects but is not intended to describe a specific sequence or precedence order. It is to be understood that data used like this may be interchangeable where appropriate, such that the embodiments of the present disclosure described herein may be implemented. Furthermore, the terms “comprise” and “have” as well as variants thereof are intended to cover non-exclusive inclusion.

Unless otherwise stated, the term “a plurality of” refers to two or more.

In the embodiments of the present disclosure, the character “/” indicates that an “or” relationship is between association objects. For example, A/B represents A or B.

The term “and/or” used for describing an association relationship between the association objects represents presence of three relationships. For example, A and/or B may represent presence of the A only, presence of both the A and the B, and presence of the B only.

The term “correspondence” may refer to an association relationship or a binding relationship, and that A corresponds to B refers to an association relationship or a binding relationship between A and B.

Currently, with the improvement of performance of servers in data centers, demands for heat dissipation of server chips and other components are also increasing accordingly.

Cold plate liquid-cooled servers are used in related technologies to solve the heat dissipation problem of the servers in the data centers. However, liquid cooling systems in the cold plate liquid-cooled servers can only dissipate heat from components with higher heat generation such as the server chips. Other components with lower heat generation in the servers rely on the servers' own cooling fans to dissipate heat, which results in lower heat dissipation efficiency.

In view of this, the embodiments of the present disclosure provide a refrigeration system and a control method for a data center, and the data center. The liquid-cooled server provided in the embodiments of the present disclosure can dissipate heat by means of a coolant distribution apparatus and a water-cooled precision air conditioner. Compared to a mode where the liquid-cooled server relies on a liquid-cooled pipeline and its own fan to dissipate heat, heat dissipation efficiency of the server in the data center can be improved.

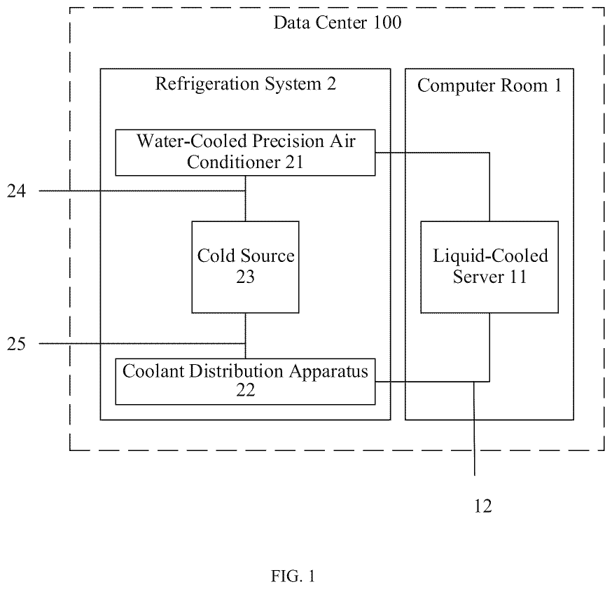

With reference to FIG. 1, the embodiments of the present disclosure provide a data center 100, which includes at least one computer room 1 and a refrigeration system 2. The computer room 1 is internally provided with at least one liquid-cooled server 11, which dissipates heat through a liquid-cooled pipeline 12. The refrigeration system 2 includes a water-cooled precision air conditioner 21, a coolant distribution apparatus 22, and a cold source 23. The water-cooled precision air conditioner 21 is configured to dissipate heat from the liquid-cooled server 11 in the computer room 1, and the coolant distribution apparatus 22 is configured to dissipate heat from the liquid-cooled pipeline 12 of the liquid-cooled server 11 in the computer room 1. The cold source 23 is provided with a chilled water circuit, which includes a first chilled water circuit 24 and a second chilled water circuit 25. The first chilled water circuit 24 is connected to the water-cooled precision air conditioner 21 to provide chilled water to the water-cooled precision air conditioner 21. The second chilled water circuit 25 is connected to the coolant distribution apparatus 22 to provide the chilled water to the coolant distribution apparatus 22.

In the data center provided by the embodiments of the present disclosure, the liquid-cooled server transfers heat generated by itself to outside of the computer room through the liquid in the liquid-cooled pipeline, to dissipate the heat from the liquid-cooled pipeline by means of the coolant distribution apparatus outside the computer room. In this way, heat can be dissipated from components with higher heat generation such as a chip of the liquid-cooled server. Heat dissipated from other components with lower heat generation in the liquid-cooled server may be dissipated into interior of the computer room (such as a channel of the computer room). The heat inside the computer room can be transferred to the outside of the computer room by means of the water-cooled precision air conditioner, to dissipate the heat inside the computer room. In this way, the liquid-cooled server provided in the embodiments of the present disclosure can dissipate heat by means of the coolant distribution apparatus and the water-cooled precision air conditioner. Compared to a mode where the liquid-cooled server relies on the liquid-cooled pipeline and its own fan to dissipate heat, the heat dissipation efficiency of the server in the data center can be improved.

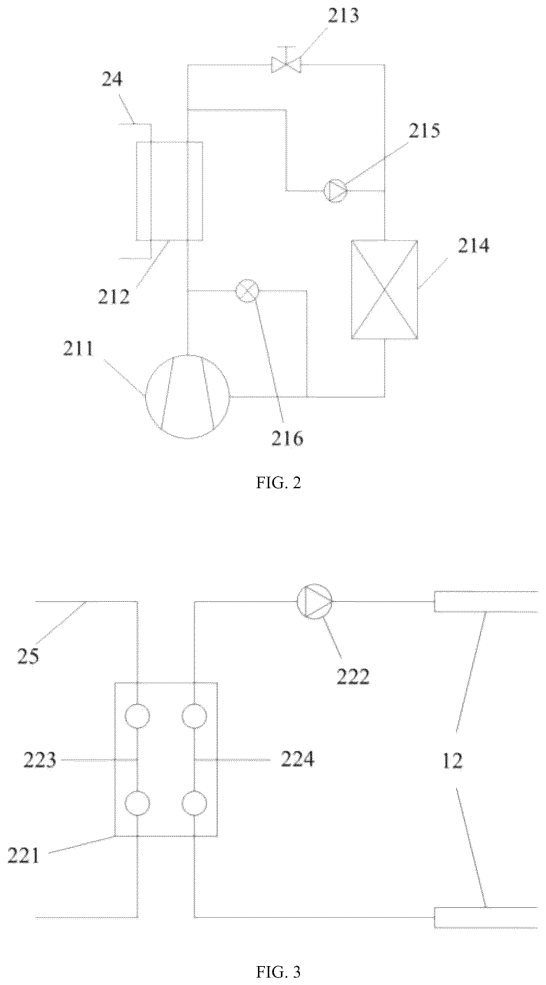

Alternatively, with reference to FIG. 2, the water-cooled precision air conditioner 21 provided in the embodiments of the present disclosure includes a compressor 211, a liquid-cooled condenser 212, an electronic expansion valve 213, an evaporator 214, a fluorine pump 215, and a one-way valve 216 that constitute a refrigerant circulation circuit. The first chilled water circuit 24 passes through the liquid-cooled condenser 212, and the chilled water in the first chilled water circuit 24 exchanges heat, in the liquid-cooled condenser 212, with a refrigerant in a refrigerant pipeline. An inlet of the fluorine pump 215 is connected to a refrigerant outlet of the liquid-cooled condenser 212 through the refrigerant pipeline, and an outlet of the fluorine pump 215 is connected to an inlet of the evaporator 214 through the refrigerant pipeline. The one-way valve 216 is arranged in parallel with the compressor 211 through the refrigerant pipeline, where an inlet of the one-way valve 216 is connected to an inlet of the compressor 211, and an outlet of the one-way valve 216 is connected to an outlet of the compressor 211. In this embodiment, the water-cooled precision air conditioner is internally provided with a fluorine pump, which may be used for circulation when ambient temperature outside the computer room is lower. Thus, it is beneficial for the water-cooled precision air conditioner to save energy.

Alternatively, with reference to FIG. 3, the coolant distribution apparatus 22 provided in the embodiments of the present disclosure includes a plate heat exchanger 221 and a water pump 222. The plate heat exchanger 221 includes a first branch 223 and a second branch 224, where the first branch 223 is communicated with the second chilled water circuit 25, the second branch 224 is communicated with the liquid-cooled pipeline 12 of the liquid-cooled server 11. The first branch 223 and the second branch 224 may exchange heat. The water pump 22 is arranged in the second branch 224, and the water pump 22 is configured to transport a liquid in the second branch 224. In this embodiment, the heat generated by the liquid-cooled server 11 may be transferred to the second branch 224 of the plate heat exchanger 221 through the liquid in the liquid-cooled pipeline 12, and may exchange heat with the chilled water in the first branch 223. Thus, heat is dissipated from the liquid-cooled server 11.

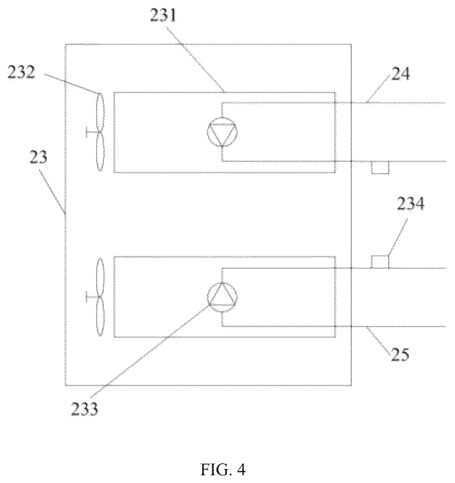

Alternatively, with reference to FIG. 4, the cold source 23 provided in the embodiments of the present disclosure also includes a cooling apparatus 231, a fan 232, a circulating pump 233, and an auxiliary heating apparatus 234. The cooling apparatus 231 and the fan 232 are configured to dissipate heat from the chilled water circuit. The circulating pump 233 is configured to transport the chilled water in the chilled water circuit.

The auxiliary heating apparatus 234 is arranged at an outlet of the first chilled water circuit 24 and an outlet of the second chilled water circuit 25, respectively. The auxiliary heating apparatus 234 is configured to heat the chilled water. In this embodiment, when the ambient temperature outside the computer room 1 is lower, the auxiliary heating apparatus 234 is turned on to heat the chilled water, which can appropriately increase the temperature of the chilled water. Thus, fluctuation of the temperature of the chilled water can be reduced, such that the water-cooled precision air conditioner 21 and the coolant distribution apparatus 22 can separately dissipate heat from the liquid-cooled server 11 by means of constant temperature chilled water. Thus, it is ensured that the liquid-cooled server 11 is in a constant temperature environment.

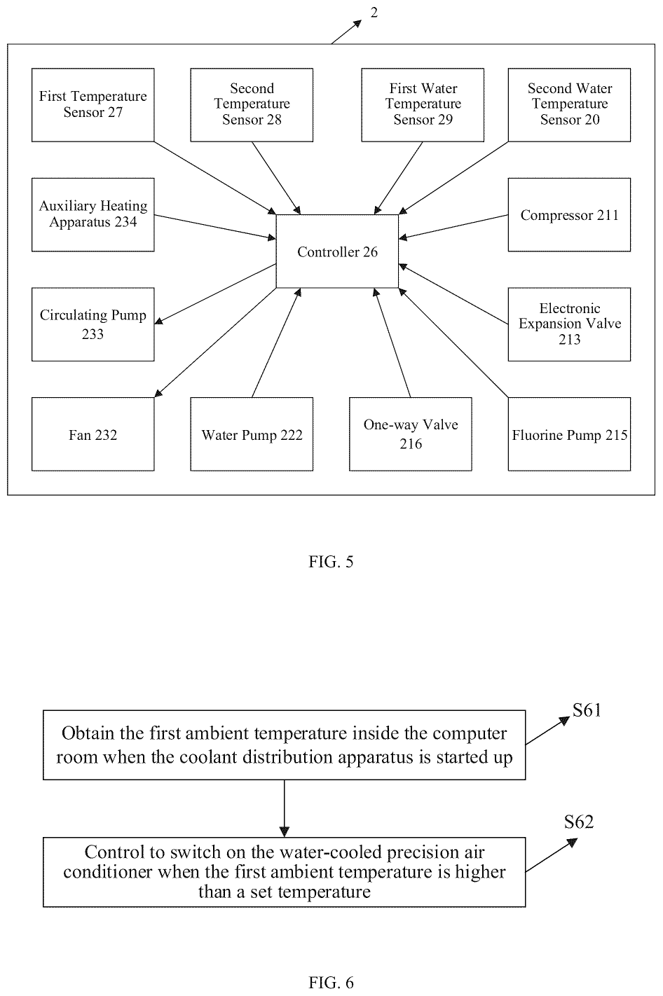

Alternatively, with reference to FIG. 5, the refrigeration system 2 provided in the embodiments of the present disclosure also includes a controller 26, a first temperature sensor 27, a second temperature sensor 28, a first water temperature sensor 29, and a second water temperature sensor 20.

The first temperature sensor 27 is configured to detect a first ambient temperature inside the computer room 1. The second temperature sensor 28 is configured to detect a second ambient temperature outside the computer room 1. The first water temperature sensor 29 is configured to detect a water temperature inside the first chilled water circuit. The second water temperature sensor 20 is configured to detect the water temperature inside the chilled water circuit.

The controller 26 is separately connected to the first temperature sensor 27, the second temperature sensor 28, the first water temperature sensor 29, and the second water temperature sensor 20, and is separately connected to the compressor 211, the electronic expansion valve 213, the fluorine pump 215, the one-way valve 216, the water pump 222, the fan 232, the circulating pump 233, and the auxiliary heating apparatus 234, and is configured to control operation thereof.

With reference to FIG. 6, the embodiments of the present disclosure provide a refrigeration control method for a data center. This method may be applied to the aforementioned refrigeration system 2, and this method may be performed by the controller 26 of the refrigeration system 2. This method includes:
Step S61: obtaining the first ambient temperature inside the computer room when the coolant distribution apparatus is started up; and
Step S62: controlling to switch on the water-cooled precision air conditioner when the first ambient temperature is higher than a set temperature.

In the embodiments of the present disclosure, the liquid-cooled server transfers heat generated by itself to outside of the computer room through the liquid in the liquid-cooled pipeline, to dissipate the heat from the liquid-cooled pipeline by means of the coolant distribution apparatus outside the computer room. In this way, heat can be dissipated from components with higher heat generation such as a chip of the liquid-cooled server. Heat dissipated from other components with lower heat generation in the liquid-cooled server may be dissipated into interior of the computer room (such as a channel of the computer room). The heat inside the computer room can be transferred to the outside of the computer room by means of the water-cooled precision air conditioner, to dissipate the heat inside the computer room. In this way, by using the refrigeration control method for the data center provided in the embodiments of the present disclosure, when the ambient temperature within the data center is higher, the liquid-cooled server can dissipate heat by means of the coolant distribution apparatus and the water-cooled precision air conditioner. Compared to a mode where the liquid-cooled server relies on the liquid-cooled pipeline and its own fan to dissipate heat, the heat dissipation efficiency of the server in the data center can be improved.

Alternatively, the compressor and the fluorine pump are controlled to be switched on when the water temperature inside the first chilled water circuit is higher than or equal to a first water temperature threshold. Or the compressor is controlled to be switched off and the fluorine pump is controlled to be switched on when the water temperature inside the first chilled water circuit is lower than the first water temperature threshold.

In this embodiment, the water-cooled precision air conditioner has lower load when the temperature of the chilled water in the first chilled water circuit is lower. At this moment, the compressor is switched off and the fluorine pump is switched on, which not only can save energy but also can ensure refrigeration effects of the water-cooled precision air conditioner.

Alternatively, the second ambient temperature outside the computer room is obtained. It is controlled to switch on the auxiliary heating apparatus when the second ambient temperature is below a first temperature threshold. In this embodiment, when the ambient temperature outside the computer room is lower, the auxiliary heating apparatus 234 is turned on to heat the chilled water, which can appropriately increase the temperature of the chilled water. Thus, fluctuation of the temperature of the chilled water can be reduced, such that the water-cooled precision air conditioner and the coolant distribution apparatus can separately dissipate heat from the liquid-cooled server by means of the constant temperature chilled water. Thus, it is ensured that the liquid-cooled server is in a constant temperature environment.

Alternatively, a rotational speed of the fan and an operating frequency of the circulating pump are decreased when the water temperature inside the chilled water circuit is below a second water temperature threshold. Or the rotational speed of the fan and the operating frequency of the circulating pump are increased when the water temperature inside the chilled water circuit is higher than the second water temperature threshold.

In this embodiment, based on the water temperature inside the chilled water circuit, the rotational speed of the fan and the operating frequency of the circulating pump may be controlled separately to indirectly control the temperature of the chilled water supplied by the cold source, which allows the cold source to supply the constant temperature chilled water, and in turn enables the water-cooled precision air conditioner and the coolant distribution apparatus to dissipate heat by means of the constant temperature chilled water, to ensure stable heat dissipation effects of the liquid-cooled server.

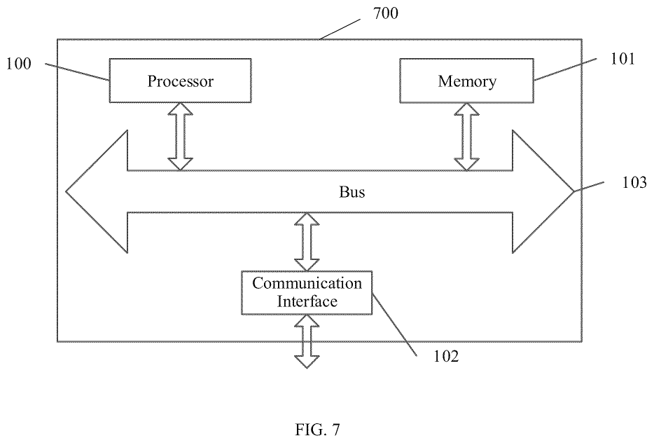

With reference to FIG. 7, the embodiments of the present disclosure also provide a refrigeration control apparatus 700 for a data center, comprising a processor 100 and a memory 101. Alternatively, the apparatus 700 may also include a communication interface 102 and a bus 103. Communications among the processor 100, the communication interface 102 and the memory 101 may be achieved by means of the bus 103. The communication interface 102 may be used for information transmission. The processor 100 can call logical instructions in the memory 101 to perform the refrigeration control method for the data center as described in the above embodiments.

In addition, when a logic instruction in the foregoing memory 101 can be implemented in the form of a software functional unit and is sold or used as an independent product, the logic instruction can be stored in a computer-readable storage medium.

As a computer-readable storage medium, the memory 101 may be configured to store software programs, computer executable programs, and program instructions/modules corresponding to the method in the embodiments of the present disclosure. The processor 100 executes functional applications and data processing by running the program instructions/modules stored in the memory 101, thus implementing the refrigeration control method for the data center as described in the above embodiments.

The memory 101 may include a program storage area and a data storage area, where the program storage area may store an operating system, application programs required for at least one function; and the data storage area may store data created according to the use of a terminal device. In addition, the memory 101 may include a high-speed random access memory, and may also include a non-volatile memory.

The technical solutions of the embodiments of the present disclosure may be embodied in the form of software products, which may be stored in a storage medium, including one or more instructions to cause a computer device (a personal computer, a server or a network device and so on) to execute all or part of steps of the method as recited in the embodiments of the present disclosure. The foregoing storage medium may be various medium that can store program codes, such as a Universal Serial Bus (USB) flash disk, a removable hard disk, a read-only memory (ROM), a random-access memory (RAM), a magnetic disk, or an optical disc. The storage medium may also be transient storage medium.

The above descriptions and the accompanying drawings fully illustrate the embodiments of the present disclosure to enable those skilled in the art to practice them. Other embodiments may include structural, logical, electrical, process, and other changes. The embodiments only represent possible changes. Unless explicitly specified, independent components and functions are optional, and an operation sequence may change. Portions and features of some embodiments can be included in, or substituted for, those of other embodiments. Moreover, the terms used in the present disclosure are only for describing the embodiments and are not intended to limit the claims. As used in the descriptions of the embodiments and the claims, singular forms “a”, “an”, and “the” are intended to also include plural forms, unless the context clearly indicates otherwise. Similarly, as used in the present disclosure, the term “and/or” refers to any and all possible combinations that include one or more associated lists. In addition, the term “comprise” and its variants such as “comprises” and/or “comprising” used in the present disclosure refer to the presence of the stated features, integers, steps, operations, elements, and/or components, but not exclusive of the presence or addition of one or more other features, integers, steps, operations, elements, components, and/or groups of thereof. In the case of no more restrictions, elements restricted by a sentence “include a” do not exclude the fact that additional identical elements may exist in a process, a method or a device of these elements. Herein, each of the embodiments is focused on difference from other embodiments, and references may be made among these embodiments with respect to the same or similar portions among these embodiments. For the methods, products, etc. disclosed in the embodiments, if they correspond to the method section disclosed in the embodiments, reference may be made to the description of the method section for relevant parts.

Those skilled in the art may realize that units and algorithm steps in various examples as described in embodiments disclosed herein can be implemented by electronic hardware or a combination of computer software and electronic hardware. Whether these functions are executed in a hardware mode or a software mode depends on specific applications and design constraints on the technical solutions. Those skilled in the art may use different methods to implement the functions set forth in each of the specific applications. However, the implementation shall be not believed beyond the scope of the embodiments of the present disclosure. Those skilled in the art may clearly understand that for a convenient and concise description, a concrete work process of systems, apparatuses and units described above may refer to a corresponding process of the foregoing method embodiments, which is not repeated anymore herein.

In the embodiments disclosed herein, the disclosed methods and products (including but not limited to apparatuses, devices, etc.) may be implemented through other means. For example, the apparatus embodiments described above are merely exemplary. For example, a unit partition is merely a logic functional partition. In actual implementation, additional manners of partitioning may be available. For example, a plurality of units or components may be combined or integrated into another system, or some features may be ignored or not executed. In addition, intercoupling or direct coupling or communications connection displayed or discussed may be indirect coupling or communications connection, electrical or mechanical or in other forms, by means of some interfaces, apparatuses or units. The unit serving as a detached component may be or not be physically detached, the component serving as a unit display may be or not be a physical unit, i.e., either located at one place or distributed on a plurality of network elements. Units may be selected in part or in whole according to actual needs to achieve this embodiment. In addition, various functional units in the embodiments of the present disclosure may be integrated into one processing unit, or various units may be separately or physically existent, or two or more units may be integrated into one unit.

The flowcharts and block diagrams in the drawings illustrate architectures, functions and operations that may be implemented according to the system, the method and the computer program product of the embodiments of the present disclosure. In this regard, each block in the flowcharts and block diagrams may represent a module, a program segment, or a code portion. The module, the program segment, or the code portion includes one or more executable instructions for implementing the specified logical function. In some alternative implementations, the functions denoted by the blocks may occur in a sequence different from the sequences shown in the drawings. For example, in practice, two blocks in succession may be executed, depending on the involved functionalities, substantially in parallel, or in a reverse sequence. In the description corresponding to the flowcharts and block diagrams in the attached drawings, the operations or steps corresponding to different blocks may also occur in a different order than disclosed in the description, and sometimes there is no specific order between different operations or steps. For example, in practice, two operations or steps in succession may be executed, depending on the involved functionalities, substantially in parallel, or in a reverse sequence. Each block in the block diagrams and/or the flowcharts and/or a combination of the blocks in the block diagrams and/or the flowcharts may be implemented by a dedicated hardware-based system executing specific functions or operations, or by a combination of a dedicated hardware and computer instructions.

What is claimed is:

1. A refrigeration system for a data center, the data center comprising a refrigeration system and at least one computer room, wherein at least one liquid-cooled server is arranged in the computer room, and the at least one liquid-cooled server dissipates heat through a liquid-cooled pipeline; and the refrigeration system comprises:
a water-cooled precision air conditioner configured to dissipate heat from the at least one liquid-cooled server in the computer room;
a coolant distribution apparatus configured to dissipate heat from the liquid-cooled pipeline of the at least one liquid-cooled server in the computer room; and
a cold source provided with a chilled water circuit comprising a first chilled water circuit and a second chilled water circuit; wherein the first chilled water circuit is connected to the water-cooled precision air conditioner to provide chilled water to the water-cooled precision air conditioner; and the second chilled water circuit is connected to the coolant distribution apparatus to provide the chilled water to the coolant distribution apparatus.

2. The refrigeration system according to claim 1, wherein the water-cooled precision air conditioner comprises a compressor, a liquid-cooled condenser, an electronic expansion valve, and an evaporator to constitute a refrigerant circulation circuit; the first chilled water circuit passes through the liquid-cooled condenser, and chilled water in the first chilled water circuit exchanges heat, in the liquid-cooled condenser, with a refrigerant in a refrigerant pipeline.

3. The refrigeration system according to claim 2, wherein the water-cooled precision air conditioner further comprises:
a fluorine pump, an inlet of the fluorine pump being connected to a refrigerant outlet of the liquid-cooled condenser through the refrigerant pipeline, and an outlet of the fluorine pump being connected to an inlet of the evaporator through the refrigerant pipeline; and
a one-way valve arranged in parallel with the compressor through the refrigerant pipeline, an inlet of the one-way valve being connected to an inlet of the compressor, and an outlet of the one-way valve being connected to an outlet of the compressor.

4. The refrigeration system according to claim 1, wherein the coolant distribution apparatus comprises:
a plate heat exchanger comprising a first branch and a second branch; the first branch being communicated with the second chilled water circuit, the second branch being communicated with the liquid-cooled pipeline of the at least one liquid-cooled server; wherein the first branch and the second branch exchange heat; and
a water pump arranged in the second branch, the water pump being configured to transport a liquid in the second branch.

5. The refrigeration system according to claim 1, wherein the cold source further comprises:
an auxiliary heating apparatus arranged at an outlet of the first chilled water circuit and an outlet of the second chilled water circuit, respectively, the auxiliary heating apparatus being configured to heat the chilled water.

6. A refrigeration control method for a data center, wherein the method is applied to a refrigeration system as claimed in claim 5, the refrigeration system further comprises a first temperature sensor configured to detect a first ambient temperature inside a computer room; and the refrigeration control method comprises:
obtaining the first ambient temperature inside the computer room when the coolant distribution apparatus is started up; and
controlling to switch on the water-cooled precision air conditioner when the first ambient temperature is higher than a set temperature.

7. The refrigeration control method according to claim 6, wherein the refrigeration system further comprises a first water temperature sensor configured to detect a water temperature inside the first chilled water circuit; and the refrigeration control method further comprises:
controlling to switch on a compressor and a fluorine pump when the water temperature inside the first chilled water circuit is higher than or equal to a first water temperature threshold; or,
controlling to switch off the compressor and to switch on the fluorine pump when the water temperature inside the first chilled water circuit is lower than the first water temperature threshold.

8. The refrigeration control method according to claim 6, wherein the cold source further comprises an auxiliary heating apparatus and a second temperature sensor; the auxiliary heating apparatus is arranged at an outlet of the first chilled water circuit and an outlet of the second chilled water circuit, respectively, and the auxiliary heating apparatus is configured to heat the chilled water; the second temperature sensor is configured to detect a second ambient temperature outside the computer room; and the refrigeration control method further comprises:
obtaining the second ambient temperature outside the computer room; and
controlling to switch on the auxiliary heating apparatus when the second ambient temperature is below a first temperature threshold.

9. The refrigeration control method according to claim 6, wherein the cold source further comprises a fan, a circulating pump, and a second water temperature sensor; the fan is configured to dissipate heat from a chilled water circuit; the circulating pump is configured to transport chilled water in the chilled water circuit; the second water temperature sensor is configured to detect water temperature inside the chilled water circuit; and the refrigeration control method further comprises:
decreasing a rotational speed of the fan and decreasing an operating frequency of the circulating pump when the water temperature inside the chilled water circuit is below a second water temperature threshold; or
increasing the rotational speed of the fan and increasing the operating frequency of the circulating pump when the water temperature inside the chilled water circuit is higher than the second water temperature threshold.

10. A data center comprising at least one computer room internally provided with at least one liquid-cooled server configured to dissipate heat through a liquid-cooled pipeline, wherein the data center further comprises a refrigeration system; and the refrigeration system comprises:
a water-cooled precision air conditioner configured to dissipate heat from the at least one liquid-cooled server in the computer room;
a coolant distribution apparatus configured to dissipate heat from the liquid-cooled pipeline of the at least one liquid-cooled server in the computer room; and
a cold source provided with a chilled water circuit comprising a first chilled water circuit and a second chilled water circuit; wherein the first chilled water circuit is connected to the water-cooled precision air conditioner to provide chilled water to the water-cooled precision air conditioner; and the second chilled water circuit is connected to the coolant distribution apparatus to provide the chilled water to the coolant distribution apparatus.

11. The data center according to claim 10, wherein the water-cooled precision air conditioner comprises a compressor, a liquid-cooled condenser, an electronic expansion valve, and an evaporator to constitute a refrigerant circulation circuit; the first chilled water circuit passes through the liquid-cooled condenser, and chilled water in the first chilled water circuit exchanges heat, in the liquid-cooled condenser, with a refrigerant in a refrigerant pipeline.

12. The data center according to claim 11, wherein the water-cooled precision air conditioner further comprises:
a fluorine pump, an inlet of the fluorine pump being connected to a refrigerant outlet of the liquid-cooled condenser through the refrigerant pipeline, and an outlet of the fluorine pump being connected to an inlet of the evaporator through the refrigerant pipeline; and
a one-way valve arranged in parallel with the compressor through the refrigerant pipeline, an inlet of the one-way valve being connected to an inlet of the compressor, and an outlet of the one-way valve being connected to an outlet of the compressor.

13. The data center according to claim 10, wherein the coolant distribution apparatus comprises:
a plate heat exchanger comprising a first branch and a second branch; the first branch being communicated with the second chilled water circuit, the second branch being communicated with the liquid-cooled pipeline of the at least one liquid-cooled server; wherein the first branch and the second branch exchange heat; and
a water pump arranged in the second branch, the water pump being configured to transport a liquid in the second branch.

14. The data center according to claim 10, wherein the cold source further comprises:
an auxiliary heating apparatus arranged at an outlet of the first chilled water circuit and an outlet of the second chilled water circuit, respectively, the auxiliary heating apparatus being configured to heat the chilled water.
